(19) United States
(12) Patent Application Publication
(10) Pub. No.: US 2026/0112441 A1
(43) Pub. Date: Apr. 23, 2026

(54) SEMICONDUCTOR DEVICE DETECTING DEFECT IN METAL LINES

(71) Applicant: SK hynix Inc., Icheon-si Gyeonggi-do (KR)

(72) Inventors: Seng Min YANG, Icheon-si Gyeonggi-do (KR); Byeong Cheol LEE, Icheon-si Gyeonggi-do (KR)

(73) Assignee: SK hynix Inc., Icheon-si Gyeonggi-do (KR)

(21) Appl. No.: 19/060,064

(22) Filed: Feb. 21, 2025

(30) Foreign Application Priority Data
Oct. 17, 2024 (KR) 10-2024-0142519

(51) Int. Cl. G11C 29/50

(52) U.S. Cl. CPC G11C 29/50; G11C 2029/5004

(57) ABSTRACT

A semiconductor device includes a power control circuit configured to generate a stress signal including pulses generated during a period that is controlled when a test mode signal is enabled and configured to apply stress to a metal line by driving the metal line based on the stress signal, and a power supply circuit configured to supply a driving voltage to a sense amplifier during an interval while a power control signal is enabled.

### CROSS-REFERENCE TO RELATED APPLICATION

The present application claims priority under 35 U.S.C. § 119(a) to Korean Patent Application No. 10-2024-0142519, filed in the Korean Intellectual Property Office on Oct. 17, 2024, the entire contents of which application is incorporated herein by reference.

### BACKGROUND

### 1. Technical Field

The present disclosure relates to semiconductor devices, including but not limited to detecting defects in semiconductor devices.

### 2. Related Art

A semiconductor memory device including double data rate synchronous DRAM (DDR SDRAM) performs read and write operations on data based on instructions input from an external chip set. The semiconductor memory device includes various circuits that perform such read and write operations, including a sense amplifier that senses and amplifies data of a memory cell.

The sense amplifier performs an operation including receiving an internal voltage when a control signal input through a metal line is generated and sensing and amplifying a voltage difference between a pair of bit lines connected to a memory cell.

### SUMMARY

In an embodiment, a semiconductor device may include a power control circuit configured to generate a stress signal including pulses generated during a period that is controlled when a test mode signal is enabled and configured to apply stress to a metal line by driving the metal line based on the stress signal, and a power supply circuit configured to supply a driving voltage to a sense amplifier during an interval while a power control signal is enabled.

In an embodiment, a semiconductor device may include a power control circuit configured to generate a selection counting signal including pulses generated during a period controlled when a test mode signal is enabled, configured to generate a stress signal based on the selection counting signal when a burn-in test signal is enabled, and configured to drive a metal line based on the stress signal; a sense amplifier configured to sense and amplify a voltage difference between a bit line and an inverted bit line in response to a driving voltage supplied during an interval while the power control signal is generated, and a defect detection circuit configured to detect a defect in the metal line by detecting a voltage level of the bit line and the inverted bit line.

In an embodiment, a method may include, during a test mode: generating a stress signal including pulses generated during one of a plurality of periods; and applying the stress signal to a metal line of a semiconductor device to stress the metal line; and during a normal mode: generating a power control signal and applying the power control signal to the metal line; and supplying a driving voltage to a sense amplifier while the power control signal is enabled.

### BRIEF DESCRIPTION OF THE DRAWINGS

FIG. 1 is a block diagram illustrating a semiconductor device according to an embodiment of the present disclosure.

FIG. 2 is a block diagram illustrating an embodiment of a stress control circuit included in the semiconductor device according to the present disclosure.

FIG. 3 is a diagram illustrating an embodiment of a counter control circuit according to the present disclosure.

FIG. 4 is a block diagram illustrating an embodiment of a counter circuit according to the present disclosure.

FIG. 5 is a timing diagram showing counting signals during operation of the counter control circuit and the counter circuit according to the present disclosure.

FIG. 6 is a block diagram illustrating an embodiment of a selection transfer circuit according to the present disclosure.

FIG. 7 is a circuit diagram illustrating an embodiment of a stress signal generation according to the present disclosure.

FIG. 8 is a block diagram illustrating an embodiment of a power supply circuit according to the present disclosure.

FIG. 9 is a circuit diagram illustrating an embodiment of a power driving circuit according to the present disclosure.

FIG. 10 is a circuit diagram illustrating an embodiment of a sense amplifier according to the present disclosure.

FIG. 11 and FIG. 12 are timing diagrams during operations including detecting a defect in metal lines in the semiconductor device according to an embodiment of the present disclosure.

FIG. 13 is a block diagram illustrating a semiconductor device according to an embodiment of the present disclosure.

FIG. 14 is a block diagram illustrating a stack memory system according to an embodiment of the present disclosure.

### DETAILED DESCRIPTION

Terms such as “top,” “under,” “over,” “on,” “lower,” “higher,” “high,” “low,” “column,” “row,” “level,” and other terms implying relative spatial relationship or orientation are utilized only for the purpose of ease of description or reference to a drawing and are not otherwise limiting.

Terms such as “first” and “second” are used to distinguish between various elements and do not imply size, order, priority, quantity, or importance of the elements. For example, a first element may be referred to as a second element in one example, and the second element may be referred to as a first element in another example.

When one component is identified as “connected” to another component, the components may be connected directly or through an intervening component between the components. When two components are identified as “directly connected,” one component is directly connected to the other component without an intervening component between the two components.

A “logic high level” and a “logic low level” are used to describe the logic levels of signals. A signal having a “logic high level” is distinguished from a signal having a “logic low level.” For example, when a signal having a first voltage corresponds to a signal having a logic high level, a signal having a second voltage corresponds to a signal having a logic low level. In an embodiment, a logic high level is a voltage higher than a voltage at a logic low level. In an embodiment, the logic levels of signals are at different logic levels or at opposite logic levels.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

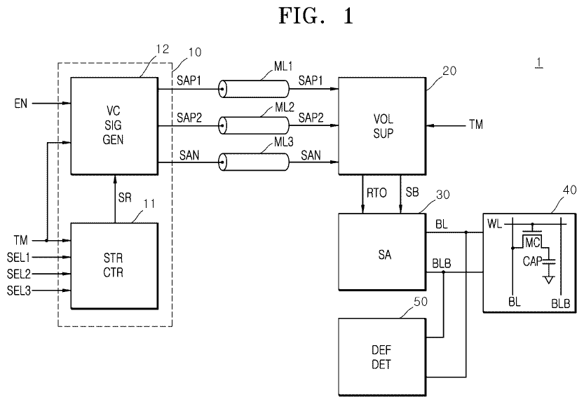

As illustrated in FIG. 1, a semiconductor device 1 according to an embodiment of the present disclosure includes a power control circuit 10, a power supply circuit VOL SUP 20, a sense amplifier SA 30, a memory circuit 40, and a defect detection circuit DEF DET 50.

The power control circuit 10 includes a stress control circuit STR CTR 11 and a power control signal generation circuit VC SIG GEN 12.

The stress control circuit 11 generates a stress signal SR in the form of pulses during a period that is controlled during a test mode. When a test mode signal TM is enabled, the stress control circuit 11 generates the stress signal SR during a period controlled based on a first selection signal SEL1, a second selection signal SEL2, and a third selection signal SEL3. The stress control circuit 11 drives a first metal line ML1, a second metal line ML2, and a third metal line ML3 based on the stress signal SR including pulses generated during a period controlled during test mode. The stress control circuit 11 drive the first metal line ML1, the second metal line ML2, and the third metal line ML3 whenever pulses of the stress signal SR are generated. The stress control circuit 11 applies stress to the first metal line ML1, the second metal line ML2, and the third metal line ML3 by driving the first metal line ML1, the second metal line ML2, and the third metal line ML3 based on the pulses of the stress signal SR. As more pulses of the stress signal SR are generated, more stress is applied to the first metal line ML1, the second metal line ML2, and the third metal line ML3.

During the normal mode, the power control signal generation circuit 12 generates a first power control signal SAP1, a second power control signal SAP2, and a third power control signal SAN that are output to the first metal line ML1, the second metal line ML2, and the third metal line ML3, respectively. When the test mode signal TM is enabled, the power control signal generation circuit 12 generates the first power control signal SAP1, the second power control signal SAP2, and the third power control signal SAN, each of which are generated at a logic low level.

The power control signal generation circuit 12 generates the first power control signal SAP1, the second power control signal SAP2, and the third power control signal SAN during a normal mode. The power control signal generation circuit 12 generates the first power control signal SAP1, the second power control signal SAP2, and the third power control signal SAN, each of which are generated at a logic high level when an enable signal EN is enabled. The power control signal generation circuit 12 generates the first power control signal SAP1, the second power control signal SAP2, and the third power control signal SAN at a logic high level during a mismatching cancellation operation when the enable signal EN is enabled. The power control signal generation circuit 12 generates the first power control signal SAP1, the second power control signal SAP2, and the third power control signal SAN at a logic high level during a sensing operation when the enable signal EN is enabled. The power control signal generation circuit 12 outputs, to the first metal line ML1, the first power control signal SAP1 generated at a logic high level when the enable signal EN is enabled. The power control signal generation circuit 12 outputs, to the second metal line ML2, the second power control signal SAP2 generated at a logic high level when the enable signal EN is enabled. The power control signal generation circuit 12 outputs, to the third metal line ML3, the third power control signal SAN generated at a logic high level when the enable signal EN is enabled. The enable signal EN is a signal that is enabled at a logic high level during operations, such as an active operation and a refresh operation, during the normal mode.

The power control circuit 10 generates the stress signal SR including pulses generated during a period controlled during the test mode. The power control circuit 10 periodically drives the first metal line ML1, the second metal line ML2, and the third metal line ML3 based on the stress signal SR. The power control circuit 10 applies stress to the first metal line ML1, the second metal line ML2, and the third metal line ML3 whenever pulses of the stress signal SR are generated during the period. The power control circuit 10 generates the first power control signal SAP1, the second power control signal SAP2, and the third power control signal SAN at a logic low level during the test mode.

The power control circuit 10 generates the first power control signal SAP1, the second power control signal SAP2, and the third power control signal SAN during the normal mode. The power control circuit 10 outputs the first power control signal SAP1 to the first metal line ML1 during the normal mode. The power control circuit 10 outputs the second power control signal SAP2 to the second metal line ML2 during the normal mode. The power control circuit 10 outputs the third power control signal SAN to the third metal line ML3 during the normal mode.

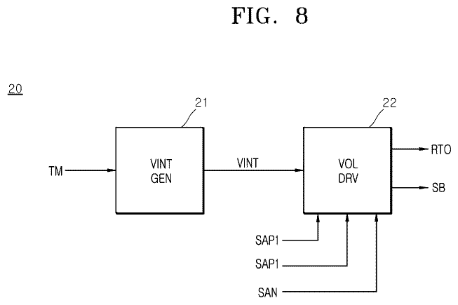

The power supply circuit 20 blocks the generation of a first driving voltage RTO and a second driving voltage SB during the test mode. The power supply circuit 20 blocks or prevents the generation of the first driving voltage RTO and the second driving voltage SB by inhibiting or blocking generation of an internal voltage, for example, VINT in FIG. 8, when the test mode signal TM is enabled.

The power supply circuit 20 generates the first driving voltage RTO and the second driving voltage SB from an internal voltage, for example, VINT in FIG. 8, during an interval while the first power control signal SAP1, the second power control signal SAP2, and the third power control signal SAN are enabled. The power supply circuit 20 supplies the first driving voltage RTO and the second driving voltage SB to the sense amplifier 30 during an interval while the first power control signal SAP1, the second power control signal SAP2, and the third power control signal SAN are enabled.

The sense amplifier 30 adjusts a voltage at a bit line BL and a voltage at an inverted bit line BLB to the same voltage during a mismatching cancellation operation during the normal mode. The mismatching cancellation operation includes adjusting a voltage at the bit line BL and a voltage at the inverted bit line BLB to the same voltage before performing an active operation during the normal mode. The sense amplifier 30 senses and amplifies a voltage difference between the bit line BL and the inverted bit line BLB during a sensing operation during the normal mode. When the first driving voltage RTO and the second driving voltage SB are generated, the sense amplifier 30 senses and amplifies a voltage difference between the bit line BL and the inverted bit line BLB. The sensing operation is an operation including sensing and amplifying a voltage difference between the bit line BL and the inverted bit line BLB during an active operation during the normal mode.

The memory circuit 40 includes a word line WL, a bit line BL, an inverted bit line BLB, a memory cell MC, and a capacitor CAP. The memory cell MC includes a gate connected to the word line WL and stores data from the bit line BL in the capacitor CAP or outputs data stored in the capacitor CAP to the bit line BL when the word line WL is activated. The inverted bit line BLB may be connected to another memory cell MC. The memory circuit 40 includes the word line WL, the bit line BL, the inverted bit line BLB, the memory cell MC, and the capacitor CAP, although the memory circuit 40 may include a plurality of word lines WL, a plurality of bit lines BL, a plurality of inverted bit lines BLB, a plurality of memory cells MC, and a plurality of capacitors CAP. The bit line BL and the inverted bit line BLB may be referred to as a bit line pair.

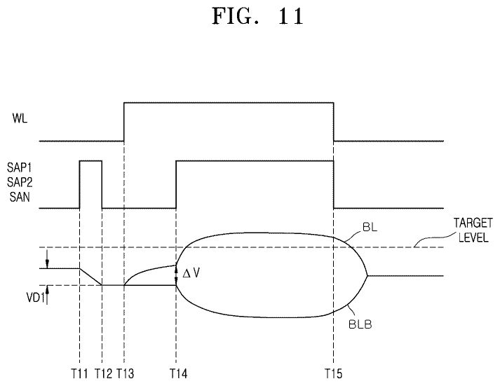

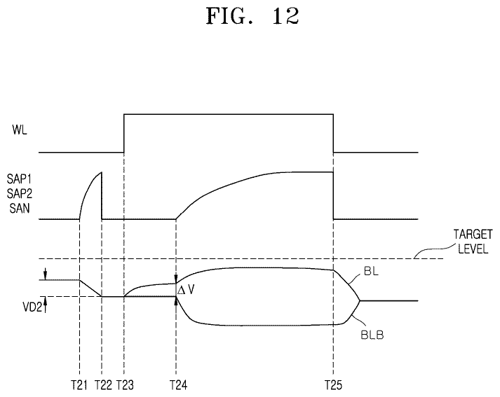

The defect detection circuit 50 detects a defect in one or more of the first metal line ML1, the second metal line ML2, and the third metal line ML3 by detecting the voltage levels at the bit line BL and the inverted bit line BLB. When one or more of the bit line BL and the inverted bit line BLB reaches a target voltage level, the defect detection circuit 50 detects that a defect is not present in any of the first metal line ML1, the second metal line ML2, and the third metal line ML3, such as shown in FIG. 11. When one or more of the bit line BL and the inverted bit line BLB does not reach the target voltage level, the defect detection circuit 50 detects a defect in one or more of the first metal line ML1, the second metal line ML2, and the third metal line ML3. A defect in one or more of the first metal line ML1, the second metal line ML2, and the third metal line ML3 may be a contact fail in one or more of the first metal line ML1, the second metal line ML2, and the third metal line ML3, which defect is detected in response to applying the stress signal SR applied during the test mode to the first metal line ML1, the second metal line ML2, and the third metal line ML3. A defect may be a short-circuit between another metal line and one or more of the first metal line ML1, the second metal line ML2, and the third metal line ML3. When a defect is present, the first power control signal SAP1, the second power control signal SAP2, and the third power control signal SAN, each having a desired voltage level, are not output because one or more of the first metal line ML1, the second metal line ML2, and the third metal line ML3 are deformed. For example, when a defect is detected in one or more of the first metal line ML1, the second metal line ML2, and the third metal line ML3, as indicated in FIG. 12, the first power control signal SAP1, the second power control signal SAP2, and the third power control signal SAN may increase slowly. When a contact fail occurs, a metal line is deformed and does not contact internal circuits. When metal lines are short-circuited, a deformed metal line is connected to another metal line.

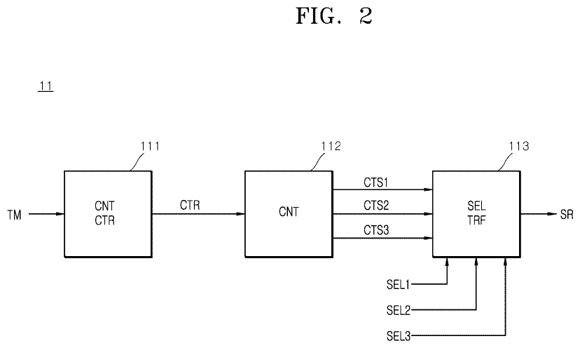

FIG. 2 is a block diagram illustrating an embodiment of the stress control circuit 11, for example, as included in the semiconductor device 1 of FIG. 1. The stress control circuit 11 includes a counter control circuit CNT CTR 111, a counter circuit CNT 112, and a selection transfer circuit SEL TRF 113.

The counter control circuit 111 generates a counting control signal CTR including pulses that are periodically generated during the test mode. While the test mode signal TM is enabled, the counter control circuit 111 generates the counting control signal CTR including pulses that are periodically generated.

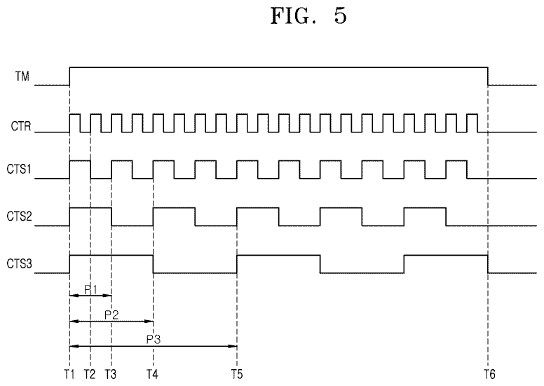

The counter circuit 112 generates a first counting signal CTS1 according to a first period P1, a second counting signal CTS2 according to a second period P2, and a third counting signal CTS3 according to a third period P3 including pulses that are generated according to the pulse of the counting control signal CTR as described with reference to FIG. 5. In response to receiving a pulse of the counting control signal CTR, the counter circuit 112 generates the first counting signal CTS1 including a pulse generated according to the first period. In response to receiving a pulse of the first counting signal CTS1, the counter circuit 112 generates the second counting signal CTS2 including a pulse generated according to a second period. In response to receiving a pulse of the second counting signal CTS2, the counter circuit 112 generates the third counting signal CTS3 including a pulse generated according to the third period. The first period is a shorter time interval than the second period. The second period is a shorter time interval than the third period. The stress applied to the metal lines ML1, ML2, and ML3 is greater when the stress signal SR is applied to the metal line during the second period than when the stress signal is applied during the first period. The stress applied to the metal lines ML1, ML2, and ML3 is greater when the stress signal SR is applied to the metal line during the third period than when the stress signal is applied during the first period or the second period.

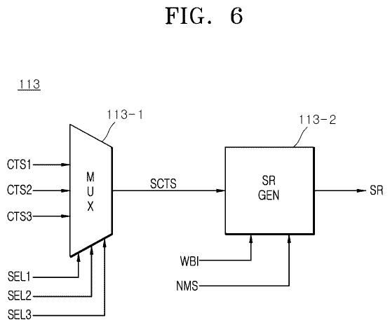

The selection transfer circuit 113 outputs one of the first counting signal CTS1, the second counting signal CTS2, and the third counting signal CTS3 as the stress signal SR based on a first selection signal SEL1, a second selection signal SEL2, and a third selection signal SEL3. When the first selection signal SEL1 is enabled, the selection transfer circuit 113 outputs the first counting signal CTS1 as the stress signal SR. When the second selection signal SEL2 is enabled, the selection transfer circuit 113 outputs the second counting signal CTS2 as the stress signal SR. When the third selection signal SEL3 is enabled, the selection transfer circuit 113 outputs the third counting signal CTS3 as the stress signal SR. The first selection signal SEL1, the second selection signal SEL2, and the third selection signal SEL3 are each a signal generated by a circuit, such as a mode register set MRS included in the semiconductor device 1, to adjust a time at which a pulse of the stress signal SR is generated. The selection transfer circuit 113 generates the stress signal SR that is disabled at a logic low level during normal mode. Operation of the selection transfer circuit 113, including generating the stress signal SR from one of the first counting signal CTS1, the second counting signal CTS2, and the third counting signal CTS3 and generating the stress signal SR that is disabled during the normal mode, are described with reference to FIG. 6.

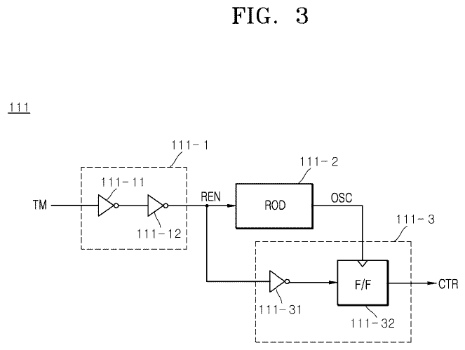

FIG. 3 is a diagram illustrating an embodiment of the counter control circuit 111, for example, as included in the stress control circuit 11 of FIG. 2. The counter control circuit 111 includes a buffer circuit 111-1, an oscillator ROD 111-2, and a latch circuit 111-3.

The buffer circuit 111-1 is implemented with inverters 111-11 and 111-12. The buffer circuit 111-1 generates a cycle enable signal REN by buffering the test mode signal TM. When the test mode signal TM is enabled at a logic high level, the buffer circuit 111-1 generates the cycle enable signal REN enabled at a logic high level.

The oscillator 111-2 generates a cycle signal OSC including pulses that are periodically generated during an interval while the cycle enable signal REN is enabled. The oscillator 111-2 may be implemented with a common ring oscillator.

The latch circuit 111-3 is implemented with an inverter 111-31 and a flip-flop F/F 111-32. The inverter 111-31 inverts and outputs the cycle enable signal REN. The flip-flop 111-32 outputs the output signal of the inverter 111-31 as the counting control signal CTR by latching the output signal in synchronization with the pulse of the cycle signal OSC. The latch circuit 111-3 generates the counting control signal CTR by latching the cycle enable signal REN in synchronization with the pulse of the cycle signal OSC.

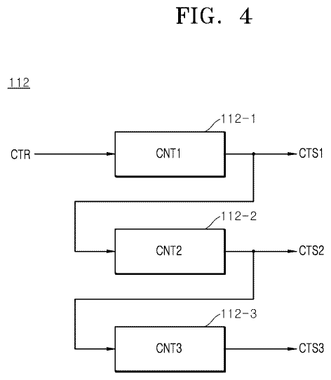

FIG. 4 is a block diagram illustrating an embodiment of the counter circuit 112, for example, as included in the stress control circuit 11 of FIG. 2. The counter circuit 112 includes a first counter CNT1 112-1, a second counter CNT2 112-2, and a third counter CNT3 112-3.

The first counter 112-1 generates the first counting signal CTS1 based on pulses of the counting control signal CTR. The first counter 112-1 generates the first counting signal CTS1 that transitions levels in response to a rising edge of a pulse of the counting control signal CTR. The first counter 112-1 generates the first counting signal CTS1 including a pulse that is generated according to a first period in synchronization with a time at which a pulse of the counting control signal CTR is generated at a logic high level.

The second counter 112-2 generates the second counting signal CTS2 based on pulses of the first counting signal CTS1. The second counter 112-2 generates the second counting signal CTS2 that transitions levels in response to a rising edge of a pulse of the first counting signal CTS1. The second counter 112-2 generates the second counting signal CTS2 including a pulse that is generated according to a second period in synchronization with a time at which a pulse of the first counting signal CTS1 is generated at a logic high level.

The third counter 112-3 generates the third counting signal CTS3 based on pulses of the second counting signal CTS2. The third counter 112-3 generates the third counting signal CTS3 that transitions levels in response to a rising edge of a pulse of the second counting signal CTS2. The third counter 112-3 generates the third counting signal CTS3 including a pulse that is generated according to a third period in synchronization with a time at which a pulse of the second counting signal CTS2 is generated at a logic high level.

FIG. 5 is a timing diagram showing counting signals during operation of the counter control circuit 111 and the counter circuit 112, for example, as shown in FIG. 3 and FIG. 4.

The test mode signal TM is enabled at a logic high level from time T1 to time T6.

The counter control circuit 111 generates the counting control signal CTR including pulses that are periodically generated during an interval while the test mode signal TM is enabled at a logic high level from time T1 to time T6.

At time T1, the first counter 112-1 generates the first counting signal CTS1, the level of which transitions from a logic low level to a logic high level at time T1 when a pulse of the counting control signal CTR is generated at a logic high level, which occurs at a rising edge of the counting control signal CTR. The second counter 112-2 generates the second counting signal CTS2 that transitions from a logic low level to a logic high level at time T1 when a pulse of the first counting signal CTS1 is generated at a logic high level, which occurs at a rising edge of the first counting signal CTS1. The third counter 112-3 generates the third counting signal CTS3 that transitions from a logic low level to a logic high level at time T1 when a pulse of the second counting signal CTS2 is generated at a logic high level, which occurs at a rising edge of the second counting signal CTS2.

At time T2, the first counter 112-1 generates the first counting signal CTS1 that transitions from a logic high level to a logic low level at time T2 when a pulse of the counting control signal CTR is generated at a logic high level.

At time T3, the first counter 112-1 generates the first counting signal CTS1 that transitions from a logic low level to a logic high level at time T3 when a pulse of the counting control signal CTR is generated at a logic high level.

Thus, the first counter 112-1 generates the first counting signal CTS1 including a pulse that is generated having a first period P1. The first period P1 is a time interval from time T1 to time T3.

At time T3, the second counter 112-2 generates the second counting signal CTS2 that transitions from a logic high level to a logic low level at time T3 when a pulse of the first counting signal CTS1 is generated at a logic high level.

At time T4, the second counter 112-2 generates the second counting signal CTS2 that transitions from a logic low level to a logic high level at time T4 when a pulse of the first counting signal CTS1 is generated at a logic high level.

Thus, the second counter 112-2 generates the second counting signal CTS2 including a pulse that is generated having a second period P2. The second period P2 is a time interval from time T1 to time T4.

At time T4, the third counter 112-3 generates the third counting signal CTS3 that transitions from a logic high level to a logic low level at time T4 when a pulse of the second counting signal CTS2 is generated at a logic high level.

At time T5, the third counter 112-3 generates the third counting signal CTS3 that transitions from a logic low level to a logic high level at time T5 when a pulse of the second counting signal CTS2 is generated at a logic high level.

Thus, the third counter 112-3 generates the third counting signal CTS3 including a pulse that is generated having a third period P3. The third period P3 is a time interval from time T1 to time T5.

FIG. 6 is a block diagram illustrating an embodiment of the selection transfer circuit 113, for example, as included in the stress control circuit 11 of FIG. 2. The selection transfer circuit 113 includes a multiplexer MUX 113-1 and a stress signal generation circuit SR GEN 113-2.

The multiplexer 113-1 outputs one of the first counting signal CTS1, the second counting signal CTS2, and the third counting signal CTS3 as a selection counting signal SCTS based on the first selection signal SEL1, the second selection signal SEL2, and the third selection signal SEL3. The multiplexer 113-1 outputs the first counting signal CTS1 as the selection counting signal SCTS when the first selection signal SEL1 is enabled. The multiplexer 113-1 outputs the second counting signal CTS2 as the selection counting signal SCTS when the second selection signal SEL2 is enabled. The multiplexer 113-1 outputs the third counting signal CTS3 as the selection counting signal SCTS when the third selection signal SEL3 is enabled.

The stress signal generation circuit 113-2 generates the stress signal SR from the selection counting signal SCTS based on a burn-in test signal WBI and a normal mode signal NMS. The stress signal generation circuit 113-2 generates the stress signal SR from the selection counting signal SCTS when the burn-in test signal WBI is enabled. The stress signal generation circuit 113-2 generates the stress signal SR disabled at a logic low level when the normal mode signal NMS is enabled.

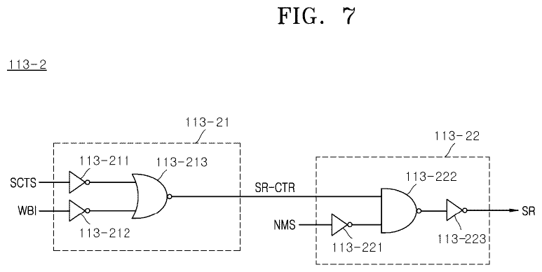

FIG. 7 is a circuit diagram illustrating an embodiment of the stress signal generation circuit 113-2, for example, as included in the selection transfer circuit 113 of FIG. 6.

The stress signal generation circuit 113-2 includes a first logic circuit 113-21 and a second logic circuit 113-22.

The first logic circuit 113-21 is implemented with inverters 113-211 and 113-212 and a NOR gate 113-213. The first logic circuit 113-21 generates a stress control signal SR-CTR by buffering the selection counting signal SCTS when the burn-in test signal WBI is enabled at a logic high level. The first logic circuit 113-21 generates the stress control signal SR-CTR disabled at a logic low level when the burn-in test signal WBI is disabled at a logic low level. The burn-in test signal WBI is a signal enabled at a logic high level during the test mode. The burn-in test signal WBI is a signal disabled at a logic low level during the normal mode.

The second logic circuit 113-22 is implemented with inverters 113-221 and 113-223 and a NAND gate 113-222. The second logic circuit 113-22 generates the stress signal SR by buffering the stress control signal SR-CTR when the normal mode signal NMS is disabled at a logic low level. The second logic circuit 113-22 generates the stress signal SR disabled at a logic low level when the normal mode signal NMS is enabled at a logic high level. The normal mode signal NMS is a signal disabled at a logic low level during the test mode. The normal mode signal NMS is a signal enabled at a logic high level during the normal mode.

FIG. 8 is a block diagram illustrating an embodiment of the power supply circuit 20, for example, as included in the semiconductor device 1 of FIG. 1. The power supply circuit 20 includes an internal voltage generation circuit VINT GEN 21 and a voltage driving circuit VOL DRV 22.

The internal voltage generation circuit 21 blocks the generation of the internal voltage VINT during the test mode. The internal voltage generation circuit 21 blocks generation of the internal voltage VINT when the test mode signal TM is enabled. The internal voltage generation circuit 21 generates the internal voltage VINT during the normal mode. The internal voltage generation circuit 21 generates the internal voltage VINT when the test mode signal TM is disabled. The internal voltage generation circuit 21 may be implemented with a common low drop-output LDO voltage regulator and may generate the internal voltage VINT at a constant voltage level.

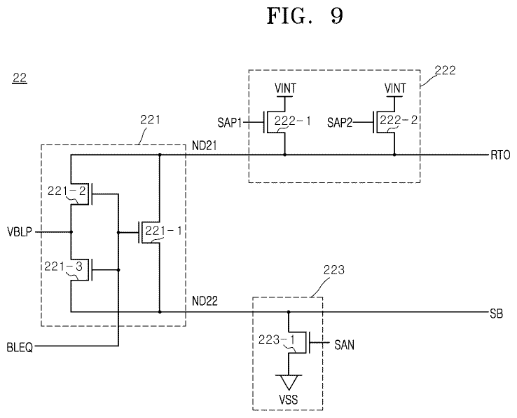

The power driving circuit 22 generates the first driving voltage RTO and the second driving voltage SB from the internal voltage VINT during an interval while the first power control signal SAP1, the second power control signal SAP2, and the third power control signal SAN are enabled. The power driving circuit 22 generates the first driving voltage RTO from the internal voltage VINT during an interval while the first power control signal SAP1 and the second power control signal SAP2 are enabled. The power driving circuit 22 generates the second driving voltage SB from a ground voltage, for example, VSS in FIG. 9, during an interval while the third power control signal SAN is enabled. The ground voltage, for example, VSS in FIG. 9, may be a common ground voltage. The power driving circuit 22 supplies the first driving voltage RTO and the second driving voltage SB to the sense amplifier 30 during the interval while the first power control signal SAP1, the second power control signal SAP2, and the third power control signal SAN are enabled.

FIG. 9 is a circuit diagram illustrating an embodiment of the power driving circuit 22, for example, as included in the power supply circuit 20 of FIG. 8. The power driving circuit 22 includes a precharge circuit 221, a first driving circuit 222, and a third driving circuit 223.

The precharge circuit 221 is implemented with NMOS transistors 221-1, 221-2, and 221-3. The NMOS transistor 221-1 is connected between a node ND21 from which the first driving voltage RTO is generated and a node ND22 from which the second driving voltage SB is generated. The NMOS transistor 221-1 connects the node ND21 and the node ND22 when an equalization signal BLEQ is enabled at a logic high level. The NMOS transistors 221-2 and 221-3 are connected between the node ND21 from which the first driving voltage RTO is generated and the node ND22 from which the second driving voltage SB is generated. The NMOS transistors 221-2 and 221-3 drive the node ND21 and the node ND22 to a precharge voltage VBLP when the equalization signal BLEQ is enabled at a logic high level. The equalization signal BLEQ is a signal enabled at a logic high level after the start of a precharge operation during the normal mode. The precharge voltage VBLP is a voltage generated at constant voltage level after the start of a precharge operation during the normal mode.

The first driving circuit 222 is implemented with NMOS transistors 222-1 and 222-2 in this example. The NMOS transistor 222-1 is connected between the internal voltage VINT and the node ND21 at which the first driving voltage RTO is generated. The NMOS transistor 222-1 generates the first driving voltage RTO by driving the node ND21 to the internal voltage VINT when the first power control signal SAP1 is enabled at a logic high level. The NMOS transistor 222-2 is connected between the internal voltage VINT and the node ND21 at which the first driving voltage RTO is generated. The NMOS transistor 222-2 generates the first driving voltage RTO by driving the node ND21 to the internal voltage VINT when the second power control signal SAP2 is enabled at a logic high level. The first power control signal SAP1 and the second power control signal SAP2 are enabled at a logic high level during a mismatching cancellation operation and a sensing operation during the normal mode.

The third driving circuit 223 is implemented with an NMOS transistor 223-1. The NMOS transistor 223-1 is connected between the node ND22 from which the second driving voltage SB is generated and the ground voltage VSS. The NMOS transistor 223-1 generates the second driving voltage SB by driving the node ND22 to the ground voltage VSS when the third power control signal SAN is enabled at a logic high level. The third power control signal SAN is enabled at a logic high level during a mismatching cancellation operation and a sensing operation during the normal mode.

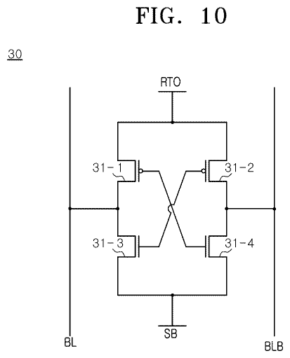

FIG. 10 is a circuit diagram illustrating an embodiment of the sense amplifier 30, for example, as included in the semiconductor device 1 of FIG. 1.

The sense amplifier 30 is implemented with PMOS transistors 31-1 and 31-2 and NMOS transistors 31-3 and 31-4. The PMOS transistor 31-1 is connected between the first driving voltage RTO and the bit line BL. The PMOS transistor 31-2 is connected between the first driving voltage RTO and the inverted bit line BLB. The NMOS transistor 31-3 is connected between the bit line BL and the second driving voltage SB. The NMOS transistor 31-4 is connected between the inverted bit line BLB and the second driving voltage SB. The gates of the PMOS transistor 31-1 and the NMOS transistor 31-4 are connected in common. The gates of the PMOS transistor 31-2 and the NMOS transistor 31-3 are connected in common.

The sense amplifier 30 senses and amplifies a voltage difference between the bit line BL and the inverted bit line BLB when the first driving voltage RTO is generated at the voltage level of the internal voltage VINT and the second driving voltage SB is generated at the voltage level of the ground voltage VSS. When the first driving voltage RTO is generated at the voltage level of the internal voltage VINT and the second driving voltage SB is generated at the voltage level of the ground voltage VSS, the sense amplifier 30 senses and amplifies a voltage difference between the bit line BL and the inverted bit line BLB, for example, ΔV in FIG. 11, in response to accessing the memory cell MC, during which process the charge stored at the capacitor CAP for the memory cell MC is “shared” with or diverted to the bit line BL. The sense amplifier 30 does sense and amplify a voltage difference between the bit line BL and the inverted bit line BLB, for example, ΔV in FIG. 11, when the first driving voltage RTO and the second driving voltage SB are not generated.

FIG. 11 and FIG. 12 are timing diagrams during operations including detecting a defect in metal lines in the semiconductor device 1 according to an embodiment of the present disclosure.

An operation including detecting a defect in metal lines of the semiconductor device 1 is described with reference to FIG. 11 according to an example in which a defect is not present in the first metal line ML1, the second metal line ML2, and the third metal line ML3.

The power control circuit 10 periodically drives the first metal line ML1, the second metal line ML2, and the third metal line ML3 based on the stress signal SR including pulses generated during a period controlled during the test mode, for example, prior to time T11 of FIG. 11. The power control circuit 10 applies stress to the first metal line ML1, the second metal line ML2, and the third metal line ML3 whenever pulses of the stress signal SR are generated.

The power control circuit 10 generates the first power control signal SAP1, the second power control signal SAP2, and the third power control signal SAN during the normal mode from time T11 to time T12.

The power supply circuit 20 generates the first driving voltage RTO from the internal voltage VINT and the second driving voltage SB from the ground voltage VSS during an interval while the first power control signal SAP1, the second power control signal SAP2, and the third power control signal SAN are enabled.

The sense amplifier 30 drives the bit line BL and the inverted bit line BLB to the same voltage level by performing a mismatching cancellation operation. In this example, the voltage levels of each of the bit line BL and the inverted bit line BLB are reduced by a first reduced-voltage level VD1.

The word line WL is activated during the normal mode from time T13 to time T15.

When the word line WL is activated at a logic high level at time T13, the voltage difference ΔV results between the bit line BL and the inverted bit line BLB because the charge at the capacitor CAP is shared with or diverted to the bit line BL.

The power control circuit 10 generates the first power control signal SAP1, the second power control signal SAP2, and the third power control signal SAN at a logic high level from time T14 to time T15 during the normal mode.

The power supply circuit 20 generates the first driving voltage RTO from the internal voltage VINT and the second driving voltage SB from the ground voltage VSS during an interval while the first power control signal SAP1, the second power control signal SAP2, and the third power control signal SAN are enabled.

The sense amplifier 30 senses and amplifies the voltage difference ΔV between the bit line BL and the inverted bit line BLB by performing a sensing operation.

The defect detection circuit 60 detects a defect in one or more of the first metal line ML1, the second metal line ML2, and the third metal line ML3 by detecting the voltage levels of the bit line BL and the inverted bit line BLB. The defect detection circuit 50 detects that a defect is not present in one or more of the first metal line ML1, the second metal line ML2, and the third metal line ML3 when the voltage level of the bit line BL reaches a target level TARGET LEVEL, indicating proper operation of the metal lines ML1, ML2, ML3.

An operation including detecting a defect in metal lines of the semiconductor device 1 is described with reference to FIG. 12 according to an example in which a defect is detected in one or more of the first metal line ML1, the second metal line ML2, and the third metal line ML3.

The power control circuit 10 periodically drives the first metal line ML1, the second metal line ML2, and the third metal line ML3 based on the stress signal SR including pulses generated during a period controlled during the test mode, for example, prior to time T21. The power control circuit 10 applies stress to the first metal line ML1, the second metal line ML2, and the third metal line ML3 whenever pulses of the stress signal SR are generated.

The power control circuit 10 generates the first power control signal SAP1, the second power control signal SAP2, and the third power control signal SAN to a logic high level from time T21 to time T22 during the normal mode. During this time interval, the voltage levels of the first power control signal SAP1, the second power control signal SAP2, and the third power control signal SAN increase slowly because a defect in one or more of the first metal line ML1, the second metal line ML2, and the third metal line ML3 results from stress applied to the first metal line ML1, the second metal line ML2, and the third metal line ML3 whenever pulses of the stress signal SR are generated. The first power control signal SAP1, the second power control signal SAP2, and the third power control signal SAN are generated at a lower voltage level than the voltage generated when a defect is not present in one or more of the first metal line ML1, the second metal line ML2, and the third metal line ML3.

The power supply circuit 20 generates the first driving voltage RTO from the internal voltage VINT and the second driving voltage SB from the ground voltage VSS during an interval while the first power control signal SAP1, the second power control signal SAP2, and the third power control signal SAN are enabled.

The sense amplifier 30 drives the bit line BL and the inverted bit line BLB to the same voltage level by performing a mismatching cancellation operation. In this example, the voltage levels of the voltage levels of the bit line BL and the inverted bit line BLB are reduced by a second reduced-voltage level VD2. The mismatching cancellation operation is performed abnormally because the second reduced-voltage level VD2 is greater than the first reduced-voltage level VD1.

The word line WL is activated during the normal mode from time T23 to time T25.

When the word line WL is activated at a logic high level at time T23, a voltage difference ΔV results between the bit line BL and the inverted bit line BLB because the charge at the capacitor CAP is shared with or diverted to the bit line BL.

The power control circuit 10 generates the first power control signal SAP1, the second power control signal SAP2, and the third power control signal SAN during the normal mode from time T24 to time T25. During this time interval, the voltage levels of the first power control signal SAP1, the second power control signal SAP2, and the third power control signal SAN increase slowly because a defect in one or more of the first metal line ML1, the second metal line ML2, and the third metal line ML3 results from stress applied whenever pulses of the stress signal SR are generated. The first power control signal SAP1, the second power control signal SAP2, and the third power control signal SAN are generated at a lower voltage level than the voltage level when a defect is not present in one or more of the first metal line ML1, the second metal line ML2, and the third metal line ML3.

The power supply circuit 20 generates the first driving voltage RTO from the internal voltage VINT and the second driving voltage SB from the ground voltage VSS during the interval while the first power control signal SAP1, the second power control signal SAP2, and the third power control signal SAN are enabled.

The sense amplifier 30 senses and amplifies the voltage difference ΔV between the bit line BL and the inverted bit line BLB by performing a sensing operation.

The defect detection circuit 60 detects a defect in one or more of the first metal line ML1, the second metal line ML2, and the third metal line ML3 by detecting the voltage levels of the bit line BL and the inverted bit line BLB. The defect detection circuit 50 detects a defect in one or more of the first metal line ML1, the second metal line ML2, and the third metal line ML3 when the voltage level of the bit line BL does not reach a target (voltage) level TARGET LEVEL.

The semiconductor device 1, according to an embodiment of the present disclosure, applies stress to metal lines for a short time without separate (outside the semiconductor device) test equipment by applying the stress to the metal lines using pulses periodically generated during the test mode. For example, the semiconductor device 1 detects a defect in metal lines during the normal mode after applying stress to the metal lines during the test mode.

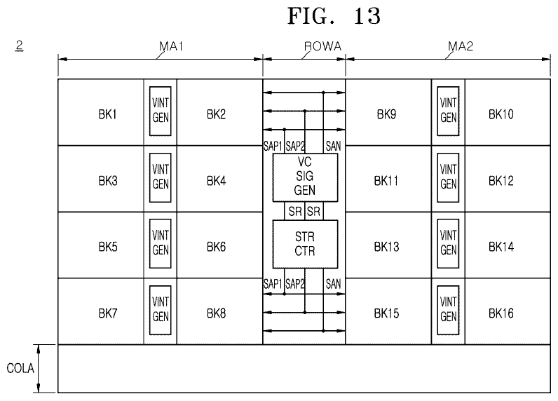

FIG. 13 is a block diagram illustrating a semiconductor device 2 according to an embodiment of the present disclosure. The semiconductor device 2includes a first memory area MA1, a second memory area MA2, a row area ROWA, and a column area COLA.

The row area ROWA is disposed between the first memory area MA1 and the second memory area MA2.

The first memory area MA1 and the second memory area MA2 may be implemented with a common memory circuit that stores and outputs data.

The row area ROWA is an area including an internal circuit that selectively activates a plurality of word lines WL included in the first memory area MA1 and the second memory area MA2.

The column area COLA may be disposed under the first memory area MA1 and the second memory area MA2.

The column area COLA is an area including an internal circuit that selectively activates a plurality of bit line pairs BL and BLB included in the first memory area MA1 and the second memory area MA2.

The first memory area MA1 includes a first bank BK1 to an eighth bank BK8.

Each of the banks BK1 to BK8 may include a power supply circuit 20, a sense amplifier 30, a memory circuit 40, and a defect detection circuit 50, such as illustrated in FIG. 1.

A plurality of internal voltage generation circuits VINT GEN, such as illustrated in FIG. 8, may be included between the banks BK1 to BK8.

The second memory area MA2 includes ninth bank BK9 to sixteenth bank BK16.

Each of the banks BK9 to BK16 may include a plurality of power supply circuits 20, a plurality of sense amplifiers 30, a plurality of memory circuits 40, and a plurality of defect detection circuits 50, such as illustrated in FIG. 1.

A plurality of internal voltage generation circuits VINT GEN, such as illustrated in FIG. 8, may be included between the banks BK9 to BK16.

The row area ROWA includes the stress control circuit STR CTR and the power control signal generation circuit VC SIG GEN, such as illustrated in FIG. 1.

The stress control circuit STR CTR generates a stress signal SR including pulses generated during a period controlled during the test mode. The stress control circuit STR CTR applies stress to metal lines by applying on the stress signal SR during the test mode.

The power control signal generation circuit VC SIG GEN may block generation of the first power control signal SAP1, the second power control signal SAP2, and the third power control signal SAN during the test mode. Alternatively, when the test mode signal TM is enabled, the power control signal generation circuit VC SIG GEN generates the first power control signal SAP1, the second power control signal SAP2, and the third power control signal SAN at a logic low level. The power control signal generation circuit VC SIG GEN generates the first power control signal SAP1, the second power control signal SAP2, and the third power control signal SAN during the normal mode. The power control signal generation circuit VC SIG GEN outputs the first power control signal SAP1, the second power control signal SAP2, and the third power control signal SAN to the banks BK1 to BK16 during the normal mode.

The semiconductor device 2, according to an embodiment of the present disclosure, applies stress to metal lines for a short time without separate (outside the semiconductor device) test equipment by applying stress to the metal lines using pulses periodically generated during the test mode. The semiconductor device 2 can detect a defect in metal lines during the normal mode, for example, after applying stress to the metal lines during the test mode.

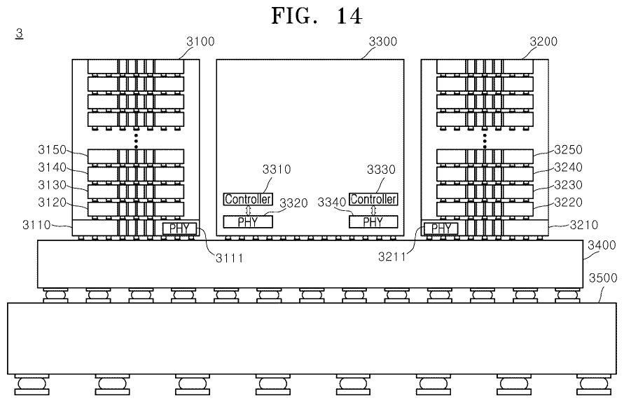

FIG. 14 is a block diagram illustrating a stack memory system 3 according to an embodiment of the present disclosure. As illustrated in FIG. 14, the stack memory system 3 includes a first stack memory device 3100, a second stack memory device 3200, a processor 3300, an interposer 3400, and a substrate 3500.

The interposer 3400 is formed on or over the substrate 3500. The first stack memory device 3100, the second stack memory device 3200, and the processor 3300 are formed on or over the interposer 3400. The processor 3300 is formed between the first stack memory device 3100 and the second stack memory device 3200. The interposer 3400 electrically connects the substrate 3500, the first stack memory device 3100, the second stack memory device 3200, and the processor 3300. Because the pitch difference between the first stack memory device 3100, the second stack memory device 3200, and the processor 3300 may be large, the first stack memory device 3100, the second stack memory device 3200, and the processor 3300 are electrically connected, for example, utilizing conductive lines that are variously formed.

The processor 3300 includes a first controller 3310 that controls the first stack memory device 3100 and a first process interface circuit PHY 3320 that electrically connects the first stack memory device 3100 and the first controller 3310. The processor 3300 includes a second controller 3330 that controls the second stack memory device 3200 and a second process interface circuit PHY 3340 that electrically connects the second stack memory device 3200 and the second controller 3330. The processor 3300 conveys signals, including a command and an address that control various internal operations of the first stack memory device 3100, to the first stack memory device 3100 through the first process interface circuit 3320 and receives signals from the first stack memory device 3100 through the first process interface circuit 3320. The processor 3300 conveys signals, including a command and an address that control various internal operations of the second stack memory device 3200, to the second stack memory device 3200 through the second process interface circuit 3340 and receives signals from the second stack memory device 3200 through the second process interface circuit 3340.

The first stack memory device 3100 includes a first base chip 3110 and first core chips 3120, 3130, 3140, and 3150. The first core chips 3120, 3130, 3140, and 3150 are implemented with the semiconductor device 1 illustrated in FIG. 1 or the semiconductor device 2 illustrated in FIG. 13, including stress signal generation circuitry, such as described with respect to FIG. 1 through FIG. 12. The first core chips 3120, 3130, 3140, and 3150 are sequentially stacked on the first base chip 3110 and receive various signals from the first base chip 3110 through TSVs, known as through vias. The first stack memory device 3100 includes the four first core chips 3120, 3130, 3140, and 3150, although various quantities of core chips, such as 4, 8, 12, 16, and other quantities may be stacked on or over the first stack memory device 3100 according to an embodiment.

The first base chip 3110 includes a first core interface circuit PHY 3111. The first core interface circuit 3111 enables communication with the first process interface circuit 3320 and receives signals from the processor 3300 and conveys, to the processor 3300, signals generated by the first core chips 3120, 3130, 3140, and 3150.

The second stack memory device 3200 includes a second base chip 3210 and second core chips 3220, 3230, 3240, and 3250. The second core chips 3220, 3230, 3240, and 3250 may be implemented with the semiconductor device 1 illustrated in FIG. 1 or the semiconductor device 2 illustrated in FIG. 13. The second core chips 3220, 3230, 3240, and 3250 are sequentially stacked on the second base chip 3210 and receive various signals from the second base chip 3210 through TSVs. The second stack memory device 3200 include the four second core chips 3220, 3230, 3240, and 3250, although various numbers of core chips, such as 4, 8, 12, 16, and other quantities may be stacked on or over the second stack memory device 3200 according to an embodiment.

The second base chip 3210 includes a second core interface circuit PHY 3211. The second core interface circuit 3211 enables communication with the second process interface circuit 3330 and receives signals from the processor 3300 and conveys, to the processor 3300, signals generated by the second core chips 3220, 3230, 3240, and 3250.

Although the detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a power control circuit configured to generate a stress signal including pulses generated during a period that is controlled when a test mode signal is enabled and configured to apply stress to a metal line by driving the metal line based on the stress signal; and
a power supply circuit configured to supply a driving voltage to a sense amplifier during an interval while a power control signal is enabled.

2. The semiconductor device of claim 1, wherein the power control circuit applies the power control signal to the metal line when the normal mode signal is enabled.

3. The semiconductor device of claim 1, wherein the power control circuit generates the power control signal when a normal mode signal is enabled.

4. The semiconductor device of claim 1,
wherein the stress applied to the metal line is greater when the stress signal is generated during a second period than when the pulse of the stress signal is generated during a first period; and
wherein the first period is a shorter time interval than the second period.

5. The semiconductor device of claim 1, wherein the power control circuit comprises:
a stress control circuit configured to generate the stress signal based on a first selection signal and a second selection signal when the test mode signal is enabled; and
a power control signal generation circuit configured to generate the power control signal when a normal mode signal is enabled and output the power control signal to the metal line.

6. The semiconductor device of claim 5, wherein the stress control circuit comprises:
a counter control circuit configured to generate a counting control signal comprising pulses periodically generated while the test mode signal is enabled;
a counter circuit configured to generate a first counting signal comprising a first pulse generated during a first period and a second counting signal comprising a second pulse generated during a second period in response to the counting control signal; and
a selection transfer circuit configured to output one of the first counting signal and the second counting signal as the stress signal based on the first selection signal and the second selection signal.

7. The semiconductor device of claim 6, wherein the counter control circuit comprises:
a buffer circuit configured to generate a cycle enable signal by buffering the test mode signal;
an oscillator configured to generate a cycle signal comprising pulses periodically generated during an interval while the cycle enable signal is enabled; and
a latch circuit configured to latch the cycle enable signal in synchronization with the cycle signal and configured to generate the counting control signal from the latched cycle enable signal.

8. The semiconductor device of claim 6, wherein the counter circuit comprises:
a first counter configured to generate the first counting signal comprising a pulse generated during the first period while pulses of the counting control signal are generated; and
a second counter configured to generate the second counting signal comprising a pulse generated during the second period while pulses of the first counting signal are generated.

9. The semiconductor device of claim 6, wherein the selection transfer circuit comprises:
a multiplexer configured to output the first counting signal as a selection counting signal when the first selection signal is enabled and configured to output the second counting signal as the selection counting signal when the second selection signal is enabled; and
a stress signal generation circuit configured to generate the stress signal from the selection counting signal when a burn-in test signal is enabled and configured to disable the stress signal while a normal mode signal is enabled.

10. The semiconductor device of claim 9, wherein the stress signal generation circuit comprises:
a first logic circuit configured to generate a stress control signal by buffering the selection counting signal when the burn-in test signal is enabled and configured to disable the stress control signal when the burn-in test signal is disabled; and
a second logic circuit configured to generate the stress signal by buffering the stress control signal when the normal mode signal is disabled and configured to disable the stress signal when the normal mode signal is enabled.

11. A semiconductor device comprising:
a power control circuit configured to generate a selection counting signal including pulses generated during a period controlled when a test mode signal is enabled, configured to generate a stress signal based on the selection counting signal when a burn-in test signal is enabled, and configured to drive a metal line based on the stress signal;
a sense amplifier configured to sense and amplify a voltage difference between a bit line and an inverted bit line in response to a driving voltage supplied during an interval while a power control signal is generated; and
a defect detection circuit configured to detect a defect in the metal line by detecting a voltage level of the bit line and the inverted bit line.

12. The semiconductor device of claim 11, wherein the defect detection circuit detects a defect in the metal line when one of the bit line and the inverted bit line does not reach a target voltage level.

13. The semiconductor device of claim 11, wherein the power control circuit applies the power control signal to the metal line when the normal mode signal is enabled.

14. The semiconductor device of claim 11, wherein the power control circuit generates the power control signal when a normal mode signal is enabled.

15. The semiconductor device of claim 11,
wherein the stress applied to the metal line is greater when the stress signal is generated during a second period than when the pulse of the stress signal is generated during a first period; and
wherein the first period is a shorter time interval than the second period.

16. The semiconductor device of claim 11, wherein the power control circuit comprises:
a stress control circuit configured to generate the stress signal based on a first selection signal and a second selection signal when the test mode signal is enabled; and
a power control signal generation circuit configured to generate the power control signal when normal mode signal is enabled and output the power control signal to the metal line.

17. The semiconductor device of claim 16, wherein the stress control circuit comprises:
a counter control circuit configured to generate a counting control signal comprising pulses periodically generated while the test mode signal is enabled;
a counter circuit configured to generate a first counting signal comprising a first pulse generated during a first period and a second counting signal comprising a pulse that is generated during a second period in response to the counting control signal; and
a selection transfer circuit configured to output one of the first counting signal and the second counting signal as the stress signal based on the first selection signal and the second selection signal.

18. The semiconductor device of claim 17, wherein the counter control circuit comprises:
a buffer circuit configured to generate a cycle enable signal by buffering the test mode signal;
an oscillator configured to generate a cycle signal comprising pulses periodically generated during an interval while the cycle enable signal is enabled; and
a latch circuit configured to latch the cycle enable signal in synchronization with the cycle signal and configured to generate the counting control signal from the latched cycle enable signal.

19. The semiconductor device of claim 17, wherein the counter circuit comprises:
a first counter configured to generate the first counting signal comprising a pulse generated during the first period while pulses of the counting control signal are generated; and
a second counter configured to generate the second counting signal comprising a pulse generated during the second period while pulses of the first counting signal are generated.

20. The semiconductor device of claim 17, wherein the selection transfer circuit comprises:
a multiplexer configured to output the first counting signal as a selection counting signal when the first selection signal is enabled and configured to output the second counting signal as the selection counting signal when the second selection signal is enabled; and
a stress signal generation circuit configured to generate the stress signal from the selection counting signal when a burn-in test signal is enabled and configured to disable the stress signal while a normal mode signal is enabled.

21. The semiconductor device of claim 11, further comprising a power supply circuit configured to supply the driving voltage to the sense amplifier during an interval while the power control signal is enabled.

22. The semiconductor device of claim 21, wherein the power supply circuit blocks the generation of the driving voltage when the test mode signal is enabled.

23. The semiconductor device of claim 21,
wherein the power control signal comprises a first power control signal, a second power control signal, and a third power control signal;
wherein the driving voltage comprises a first driving voltage and a second driving voltage;
wherein the power supply circuit comprises a first driving circuit configured to generate the first driving voltage from an internal voltage when the first power control signal and the second power control signal are enabled; and
wherein the power supply circuit comprises a second driving circuit configured to generate the second driving voltage from a ground voltage when the third power control signal is enabled.

24. The semiconductor device of claim 23, wherein the sense amplifier senses and amplifies the voltage difference between the bit line and an inverted bit line while the first driving voltage and the second driving voltage are generated.

25. A method comprising:
during a test mode:
generating a stress signal including pulses generated during one of a plurality of periods; and
applying the stress signal to a metal line of a semiconductor device to stress the metal line; and
during a normal mode:
generating a power control signal and applying the power control signal to the metal line; and
supplying a driving voltage to a sense amplifier while the power control signal is enabled.
